(19) United States
(12) Patent Application Publication
(10) Pub. No.: US 2003/0057528 A1
(43) Pub. Date: Mar. 27, 2003

(54) Semiconductor device with copper fuse section

(76) Inventor: Makoto Sasaki, Tokyo (JP)

Correspondence Address: MCGINN & GIBB, PLLC, 8321 OLD COURTHOUSE ROAD, SUITE 200, VIENNA, VA, 22182-3817, US

(21) Appl. No.: 09/532,892

(22) Filed: Mar. 22, 2000

(30) Foreign Application Priority Data
Apr. 27, 1999 (JP) 120408/1999

(51) Int. Cl. H01L 23/58

(52) U.S. Cl. 257/665

(57) ABSTRACT

A semiconductor memory device includes a dielectric film, first and second wiring lines, a copper fuse section and an opening. The first and second wiring lines are provided in the dielectric film. The copper fuse section is provided in the dielectric film, and is connected to the first and second wiring lines. The opening is formed to the copper fuse section through the dielectric film. A laser beam is irradiated to the copper fuse section through the opening in an oxygen atmosphere.

### BACKGROUND OF THE INVENTION

1. Field of the Invention

The present invention relates to a semiconductor device, and more particularly to a semiconductor device and a method of converting a copper fuse section into a high resistance section.

2. Description of the Related Art

A DRAM having a memory section in which memory cells are arranged in a matrix is known. When a part of the memory cells has a fault, a block of spare memory cells called a redundant memory cell block is used in place of a row or column of memory cells containing the fault memory cell. At this time, a fuse section provided in a wiring line is melt and cut and a circuit connection is changed for the redundant memory cell block to be used instead of the row or column of memory cells containing the fault memory cell.

A selective etching method using resist and a laser melting and cutting method are known as the technique for the cutting of such a fuse section. The selective etching requires a plurality of processes such as an application process, an exposure process and a development process, and therefore the process cost becomes high.

When Al used as a wiring line material is cut by a laser beam, the cutting point is locally heated by the laser beam. When the fuse section is formed on the surface of a low dielectric constant film, such local heating degrades the low dielectric constant film. The melting point of Al is 660° C. and is higher than 400° C. which is usual heat endurance temperature of the low dielectric constant film. A fuse processing method is known in Japanese Laid Open Patent Application (JP-A-Showa 60-84835). In this technique, a fuse section made from Al (aluminun) is heated by a laser beam in an oxidation atmosphere. The fuse section is oxidized without being melt down to change Al into alumina. That is, such a local portion of the fuse section is converted into a high resistance portion. Thus, the substantially same effect as the effect of being melt down is attained.

It is evident that Al is converted into alumina having a high resistance, when Al is oxidized. However, the conversion into alumina occurs in only the surface portion of the fuse section. It is difficult in actual to convert the whole Al fuse section into a high resistance section. If the whole Al fuse section is converted into the high resistance section, a dielectric constant layer adjacent to the fuse section is damaged so that the property of the dielectric constant layer changes. Such technique is not realistic.

In conjunction with the above description, a semiconductor integrated circuit is disclosed in Japanese Laid Open Patent Application (JP-A-Showa 59-18658). In this reference, a fuse section is made from molybdenum.

Also, a method of manufacturing a semiconductor device is in Japanese Laid Open Patent Application (JP-A-Showa 59-108329). In this reference, an energy beam is irradiated to a fuse film of polysilicon in an oxidization atmosphere to oxidize the fuse film. The energy beam has such an energy that the fuse film is not melt down.

### SUMMARY OF THE INVENTION

An object of the present invention is to provide a semiconductor device and a method of manufacturing the same, in which a copper fuse section is provided.

An object of the present invention is to provide a semiconductor device and a method of manufacturing the same, in which a fuse section can be converted into a high resistance section without degradation of a dielectric constant film adjacent to the fuse section.

In order to achieve an aspect of the present invention, a semiconductor device includes a dielectric film, first and second wiring lines, a copper fuse section and an opening. The first and second wiring lines are provided in the dielectric film, and the copper fuse section is provided in the dielectric film, and is connected to the first and second wiring lines. The opening is formed to the copper fuse section through the dielectric film. A laser beam is irradiated to the copper fuse section through the opening in an oxygen atmosphere.

It is preferable that the dielectric film has a thermal endurance of 350° C. or above, and that the dielectric film has a relative dielectric constant equal to or lower than 4.

Also, it is preferable that at least one of the first and second wiring lines is formed of copper.

Also, the copper fuse section may be connected to the first wiring line via a first conductive plug and to the second wiring line via a second conductive plug.

Also, the dielectric film may include a first dielectric film and a second dielectric film on the first dielectric film, the copper fuse section being formed on the first dielectric film. In this case, the semiconductor device further comprises a third wiring line formed of copper.

In order to achieve another aspect of the present invention, a method of converting a fuse section into a high resistance section, is attained by providing a copper fuse section in a dielectric film, an opening being formed to the copper fuse section through the dielectric film; and by irradiating a laser beam to the copper fuse section through the opening such that the copper fuse section is oxidized.

The laser beam may be irradiated to the copper fuse section in an oxygen atmosphere.

Also, it is preferable that the laser beam is irradiated to the copper fuse section such that the copper fuse section is not increased to 350° C. or above in temperature.

Also, the laser beam may be chopped. At this time, the chopped laser beam is irradiated to the copper fuse section.

Also, the laser beam may be irradiated to the copper fuse section such that a relative dielectric constant of the dielectric film is not substantially changed before and after the oxidization of the copper fuse section.

It is preferable that the dielectric film has a thermal endurance of 350° C. or above, and that the dielectric film has a relative dielectric constant equal to or lower than 4.

### BRIEF DESCRIPTION OF THE DRAWINGS

FIG. 1 is a cross sectional view showing a semiconductor device according to a first embodiment of the present invention;

FIG. 2 is a plan view the semiconductor device according to a first embodiment of the present invention;

FIG. 3 is a cross sectional view of the semiconductor device according to the first embodiment of the present invention along the line III-III of FIG. 2;

FIG. 4 is a cross sectional view of the semiconductor device according to the first embodiment of the present invention along the line I-I of FIG. 2 to show a method of converting a fuse section into a high resistance section;

FIG. 5 is a cross sectional view of the semiconductor device according to the first embodiment of the present invention along the line III-III of FIG. 2 to show a method of converting a fuse section into a high resistance section;

FIG. 6 is a graph showing experiment data; and

FIG. 7 is a graph showing another experiment data.

### DESCRIPTION OF THE PREFERRED EMBODIMENTS

Hereinafter, a semiconductor device such as a DRAM of the present invention will be described below in detail with reference to the attached drawings.

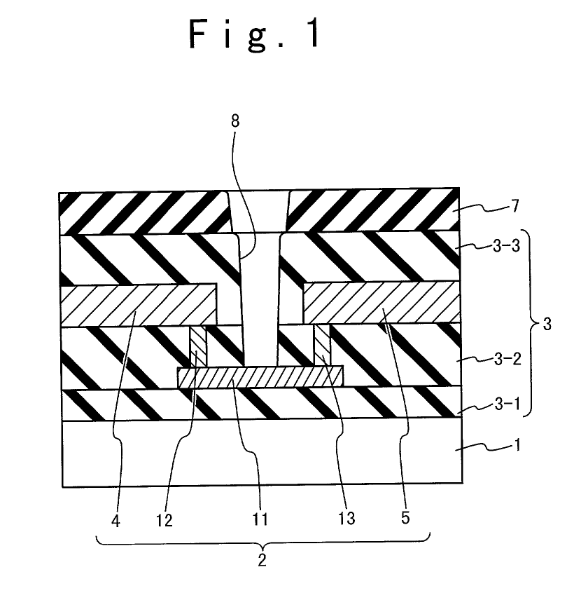

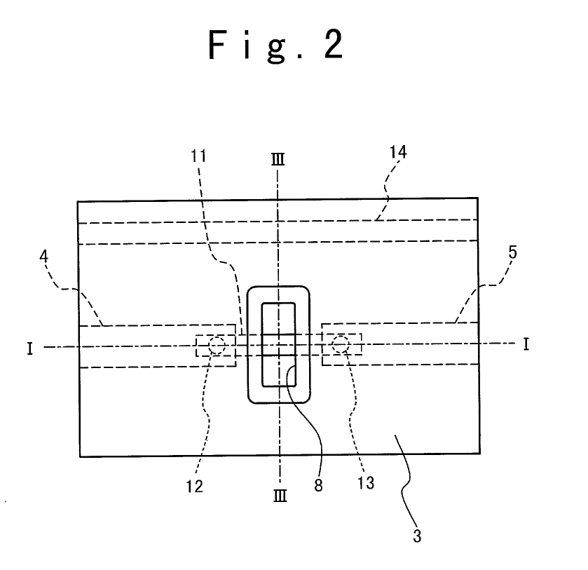

FIG. 1 is a cross sectional view showing a semiconductor device according to the first embodiment of the present invention. FIG. 2 is a plan view showing the semiconductor device.

As shown in FIG. 1, a low dielectric constant film 3 is formed on a silicon substrate 1 in the DRAM. The low dielectric constant film 3 is composed of film sections 3-1, 3-2 and 3-3 which are laminated in order. A wiring line structure 2 is formed in the low dielectric constant insulating film 3. The wiring line structure 2 is composed of wiring lines 4, 5, 12 and 13 and a fuse section 11. The wiring lines 4 and 5 are formed on the film section 3-2 of the low dielectric film 3. The fuse section 11 is formed on the film section 3-1 of the low dielectric film 3. As shown in FIGS. 1 and 2, the low dielectric constant film 3 is covered by a passivation film 7 in the area between the wiring lines 4 and 5. A laser opening 8 is formed to the fuse section 11 through the passivation film 7 and the low dielectric constant insulating film 3 in the area between the wiring lines 4 and 5.

Referring to FIG. 2, another wiring line 14 is provided in the low dielectric constant insulating film 3 in the parallel to the fuse section 11 in the same height as the fuse section 11 from the substrate 1. The wiring line 14 is formed on the film section 3-1 of the low dielectric film 3. The wiring line 14 is formed at the same time as the fuse section is formed. Any fuse section is not provided for the wiring line 14 in the region shown in FIGS. 1 and 2.

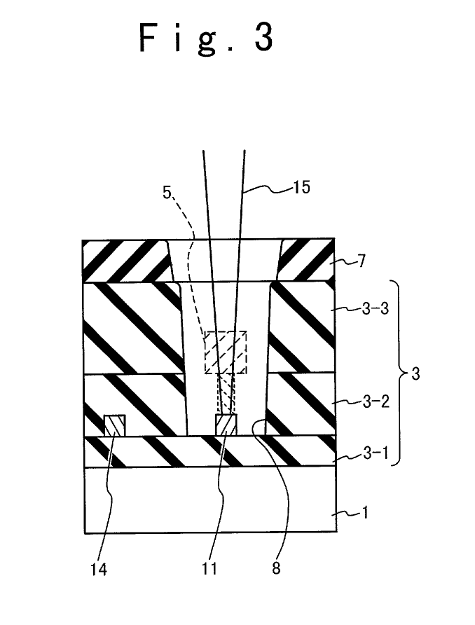

FIGS. 3, 4 and 5 show cross sectional structures of the semiconductor device according to the embodiment of the present invention.

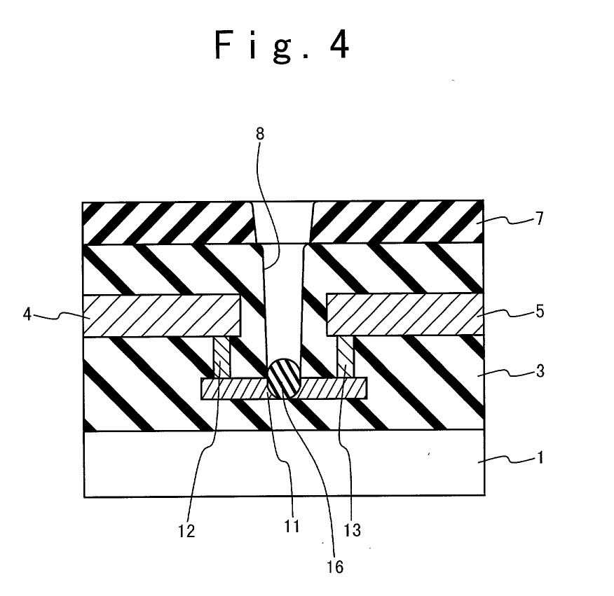

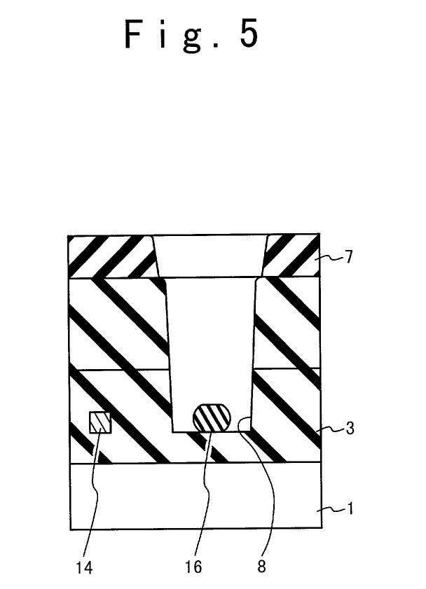

As shown in FIG. 3, a laser beam with the wavelength of about 5000 angstroms is collected to have the diameter of about 0.5 micrometers, and is irradiated to the fuse section 11 through the laser opening 8. The laser beam is chopped such that the fuse section 11 is not over-heated. Such irradiation of the laser beam is carried out in an oxygen atmosphere in which the fuse section 11 is exposed. The fuse section 11 is formed out of copper (Cu). The copper fuse section 11 is heated and oxidized with the irradiated laser beam 15. The oxidation of copper is different from the oxidation of Al, in which only the surface is converted into alumina so that the oxidation does not proceed to the inner deep portion. The copper oxide 16 changes to a porous material as shown in FIGS. 4 and 5 in response to the irradiation of the laser beam in the oxygen atmosphere. At this time, because the copper oxide 16 is exposed in the oxygen atmosphere, the oxidation proceeds promptly to the inner deep portion.

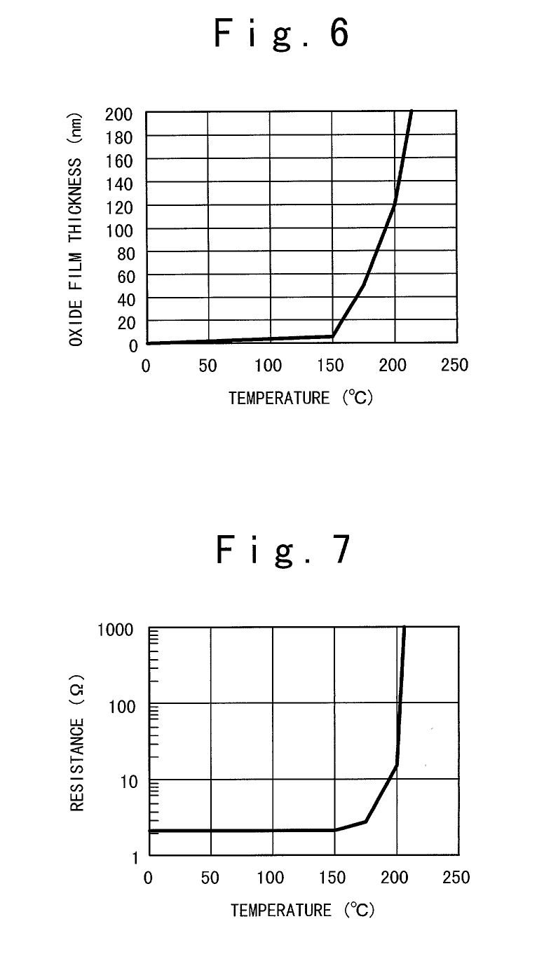

FIG. 6 shows a data when the laser beam with a pulse duration is irradiated to the copper layer in the oxygen atmosphere of 1 atm. The horizontal axis indicates a temperature and the vertical axis indicates the film thickness of the copper oxide. The film thickness of the copper oxide increases with the temperature increase when the temperature exceeds 150° C. The film thickness of the copper oxide increases rapidly when the temperature exceeds 200° C. FIG. 7 shows the change of the resistance value at that time. When the temperature exceeds 200° C., the resistance value increases remarkably. In this way, copper is different from Al in that copper is oxidized promptly to the inner deep portion at the low temperature and the resistance value increases rapidly. As shown in FIGS. 4 and 5, the copper oxide 16 is not melt down and kept within 350° C. Thus, the low dielectric constant insulating film 3 is not directly irradiated with the laser beam. Also, the low dielectric constant insulating film 3 is not heated through the fuse section to exceed its heat endurance temperature. As a result, the degradation of the low dielectric constant insulating film 3 is prevented.

The following table 1 shows the relative dielectric constant and heat endurance of the low dielectric constant insulating film.

The melting point of copper is 1083° C., and if the copper fuse section 11 is locally melt down, the low dielectric constant insulating film in the table loses its properties. According to the method of the present invention, the properties of the low dielectric constant insulating film 3 can be maintained through oxidization of the copper fuse section at the temperature of 350° C. or below. Moreover, copper may be used for the wiring lines 4, 5 and 14 other than the fuse section 11. In this case, the fuse section 11 and the wiring line 14 can be formed at the same time. Also, the wiring line resistance can be decreased.

TABLE 1

| low | relative | |
|---|---|---|
| permittivity | dielectric | |
| insulating film | constant | heat endurance |
| SiO₂ | 4 | 700° C. or above |
| SiOF | 3.5 to 3/8 | 700° C. or above |
| α-C:F | 2.3 to 2.5 | 400° C. |
| parylene | 2.3− to 2.7 | 350° C. |
| HSQ | 2.8 to 3.5 | 400° C. |
| organic SOG | 3.0 to 3.5 | 650° C. |

SiOF: fluorine containing silicon oxide
α-C:F: Fluorine containing amorphous carbon
parylene: Polypara-xylylene
HSQ: Hydrogen silsesquioxane

According to the semiconductor device of the present invention, the copper fuse section is converted into a high resistance section at relative low temperature. Therefore, the adjacent low dielectric constant insulating film is not degraded so that capacitance between the wiring lines does not increase. Also, if copper is used for a wiring line, the wiring line and the fuse section can be formed at the same time and the wiring line resistance can be decreased, so that the semiconductor device can be provided to have a large capacity and a high speed operation.

What is claimed is:

1. A semiconductor memory device comprising:
a dielectric film;
first and second wiring lines provided in said dielectric film;
a copper fuse section provided in said dielectric film, and connected to said first and second wiring lines; and
an opening formed to said copper fuse section through said dielectric film, wherein a laser beam is irradiated to said copper fuse section through said opening in an oxygen atmosphere.

2. A semiconductor memory device according to claim 1, wherein said dielectric film has a thermal endurance of 350° C. or above.

3. A semiconductor memory device according to claim 1, wherein said dielectric film has a relative dielectric constant equal to or lower than 4.

4. A semiconductor memory device according to claim 1, wherein at least one of said first and second wiring lines is formed of copper.

5. A semiconductor memory device according to claim 2, wherein at least one of said first and second wiring lines is formed of copper.

6. A semiconductor memory device according to claim 1, wherein said copper fuse section is connected to said first wiring line via a first conductive plug and to said second wiring line via a second conductive plug.

7. A semiconductor memory device according to claim 1, wherein said dielectric film includes a first dielectric film and a second dielectric film on the first dielectric film, said copper fuse section being formed on said first dielectric film, and said semiconductor memory device further comprises a third wiring line formed of copper on said first dielectric film.

8. A method of converting a fuse section into a high resistance section, comprising:
providing a copper fuse section in a dielectric film, an opening is formed to said copper fuse section through said dielectric film; and
irradiating a laser beam to said copper fuse section through said opening such that said copper fuse section is oxidized.

9. A method according to claim 8, wherein said irradiating includes:
irradiating said laser beam to said copper fuse section in an oxygen atmosphere.

10. A method according to claim 8, wherein said irradiating includes:
irradiating said laser beam to said copper fuse section such that said copper fuse section is not increased to 350° C. or above in temperature.

11. A method according to claim 8, wherein said irradiating includes:
chopping said laser beam; and
irradiating said chopped laser beam to said copper fuse section.

12. A method according to claim 8, wherein said irradiating includes:
irradiating said laser beam to said copper fuse section such that a relative dielectric constant of said dielectric film is not substantially changed before and after the oxidization of said copper fuse section.

13. A method according to claim 8, wherein said dielectric film has a thermal endurance of 350° C. or above.

14. A method according to claim 12, wherein said dielectric film has said relative dielectric constant equal to or lower than 4.
